(19) United States
(12) Patent Application Publication
(10) Pub. No.: US 2013/0062758 A1
(43) Pub. Date: Mar. 14, 2013

(54) SEMICONDUCTOR DEVICE

(71) Applicants: Takashi IMOTO, Yokkaichi-shi (JP); Yoriyasu Ando, Yokkaichi-shi (JP); Akira Tanimoto, Yokkaichi-shi (JP); Masaji Iwamoto, Yokohama-shi (JP); Yasuo Takemoto, Kamakura-shi (JP); Hideo Taguchi, Yokkaichi-shi (JP); Naoto Takebe, Yokkaichi-shi (JP); Koichi Miyashita, Yokkaichi-shi (JP); Jun Tanaka, Yokkaichi-shi (JP); Katsuhiro Ishida, Yokkaichi-shi (JP); Shogo Watanabe, Yokkaichi-shi (JP); Yuichi Sano, Yokkaichi-shi (JP)

(72) Inventors: Takashi IMOTO, Yokkaichi-shi (JP); Yoriyasu Ando, Yokkaichi-shi (JP); Akira Tanimoto, Yokkaichi-shi (JP); Masaji Iwamoto, Yokohama-shi (JP); Yasuo Takemoto, Kamakura-shi (JP); Hideo Taguchi, Yokkaichi-shi (JP); Naoto Takebe, Yokkaichi-shi (JP); Koichi Miyashita, Yokkaichi-shi (JP); Jun Tanaka, Yokkaichi-shi (JP); Katsuhiro Ishida, Yokkaichi-shi (JP); Shogo Watanabe, Yokkaichi-shi (JP); Yuichi Sano, Yokkaichi-shi (JP)

(73) Assignee: Kabushiki Kaisha Toshiba, Tokyo (JP)

(21) Appl. No.: 13/422,424

(22) Filed: Mar. 16, 2012

(30) Foreign Application Priority Data
Sep. 12, 2011 (JP) 2011-198888

(51) Int. Cl. H01L 25/07; H01L 23/48

(52) U.S. Cl. 257/737; 257/777; 257/E25.018; 257/E23.01

(57) ABSTRACT

In one embodiment, a semiconductor device has a substrate, a first semiconductor chip, an electrode, a first and second connection member, and a first and second sealing member. The electrode is disposed on the first semiconductor chip and contains Al. The first connection member electrically connects the electrode and the substrate and contains Au or Cu. The first sealing member seals the first semiconductor chip and the first connection member. One or more second semiconductor chips are stacked on the first sealing member. The second sealing member seals the first connection member, the one or more second semiconductor chips, and the one or more second connection members. A ratio of a total weight W1 of Cl ions and Br ions in the first sealing member to a weight W0 of resins of the substrate and the first sealing member is 7.5 ppm or lower.

### CROSS-REFERENCE TO RELATED APPLICATION

This application is based upon and claims the benefit of priority from the prior Japanese Patent Application No. 2011-198888, filed on Sep. 12, 2011; the entire contents of which are incorporated herein by reference.

### FIELD

Embodiments described herein relate generally to a semiconductor device in which plural semiconductor chips are stacked.

### BACKGROUND

There are semiconductor packages in which a memory chip (memory element) and a control chip (control element, system LSI) controlling writing and reading of data to/from this memory chip are stacked.

For stacking a control chip and a memory chip in this manner, there are an approach to use plural semiconductor packages (multiple package structure) and an approach to use a single semiconductor package (single package structure). In the multiple package structure, the semiconductor package of the control chip and the semiconductor package of the memory chip are stacked (Package On Package). In the single package structure, the control chip and the memory chip are disposed in parallel or stacked on one substrate, thereby forming a semiconductor package.

In the multiple package structure, it is possible to set a connection between the chip and the substrate in each semiconductor package, thereby facilitating a high-speed operation. However, the multiple package structure is disadvantageous in thickness and costs.

On the other hand, the single package structure is more advantageous in thickness and costs than the multiple package structure. However, the connection relationship between the chip and the substrate tends to be complicated. Further, over the long term, it is possible that securing reliability of electrical connection in the package becomes difficult.

### BRIEF DESCRIPTION OF THE DRAWINGS

FIG. 1 is a plan view of a semiconductor device according to a first embodiment.

FIG. 2A and FIG. 2B are side views of the semiconductor device according to the first embodiment.

FIG. 3 is an enlarged cross-sectional view of the semiconductor device according to the first embodiment.

FIG. 4 is a flowchart illustrating a production procedure of the semiconductor device according to the first embodiment.

FIG. 5A and FIG. 5B are side views of the semiconductor device produced following the procedure of FIG. 4.

FIG. 6A and FIG. 6B are side views of the semiconductor device produced following the procedure of FIG. 4.

FIG. 7A and FIG. 7B are side views of the semiconductor device produced following the procedure of FIG. 4.

FIG. 8A and FIG. 8B are side views of the semiconductor device produced following the procedure of FIG. 4.

FIG. 9A and FIG. 9B are side views of a semiconductor device according to a second embodiment.

FIG. 10 is an enlarged cross-sectional view of the semiconductor device according to the second embodiment.

FIG. 11 is a flowchart illustrating a production procedure of the semiconductor device according to the second embodiment.

FIG. 12 is a graph representing temperature dependency of the viscosity of a resin material for a sealing member 31.

FIG. 13A and FIG. 13B are microphotographs representing a lamellar structure LS occurring in a joining part of bonding wires B1 and electrodes 21a to 21d.

FIG. 14 is a microphotograph representing an alloy layer of Au and Al.

FIG. 15A and FIG. 15B are views describing the mechanism of occurrence of the lamellar structure LS.

FIG. 16 is a diagram illustrating results of an accelerated test.

### DETAILED DESCRIPTION

In one embodiment, a semiconductor device has a substrate, a first semiconductor chip, an electrode, a first and second connection member, and a first and second sealing member. The first semiconductor chip is disposed on the substrate. The electrode is disposed on the first semiconductor chip and contains Al. The first connection member electrically connects the electrode and the substrate and contains Au or Cu. The first sealing member seals the first semiconductor chip and the first connection member. One or more second semiconductor chips are stacked on the first sealing member. One or more second connection members electrically connect the one or more second semiconductor chips and the substrate. The second sealing member seals the first connection member, the one or more second semiconductor chips, and the one or more second connection members. A ratio of a total weight W1 of Cl ions and Br ions in the first sealing member to a weight W0 of resins of the substrate and the first sealing member is 7.5 ppm or lower.

Hereinafter, embodiments will be described in detail with reference to the drawings.

### First Embodiment

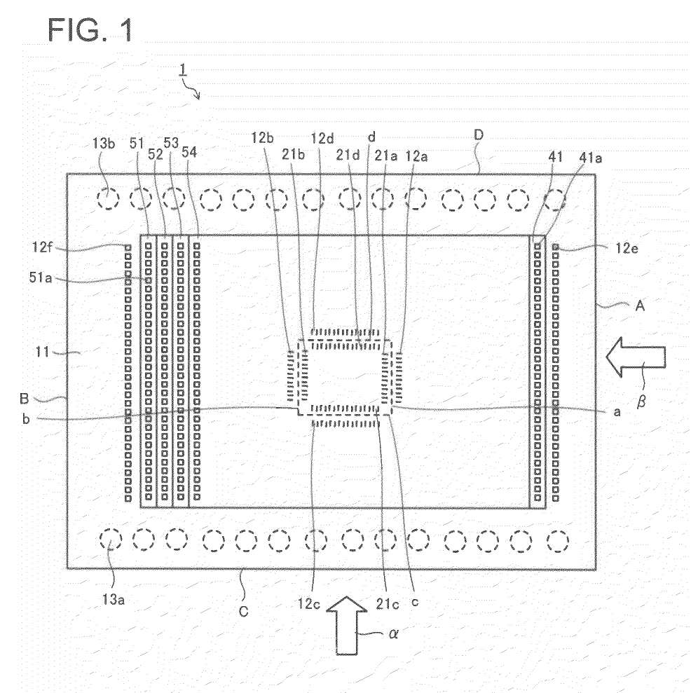

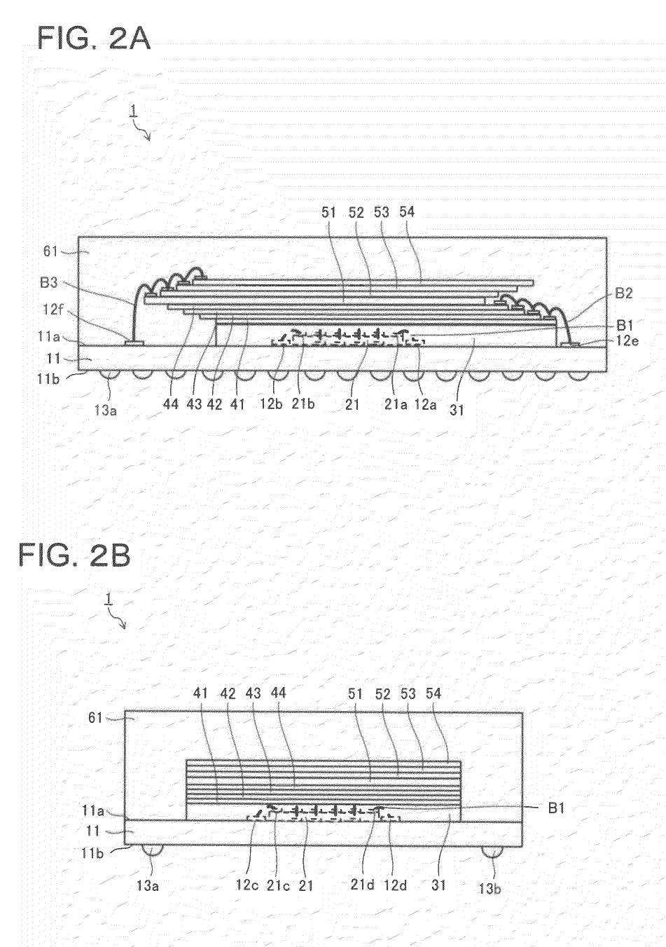

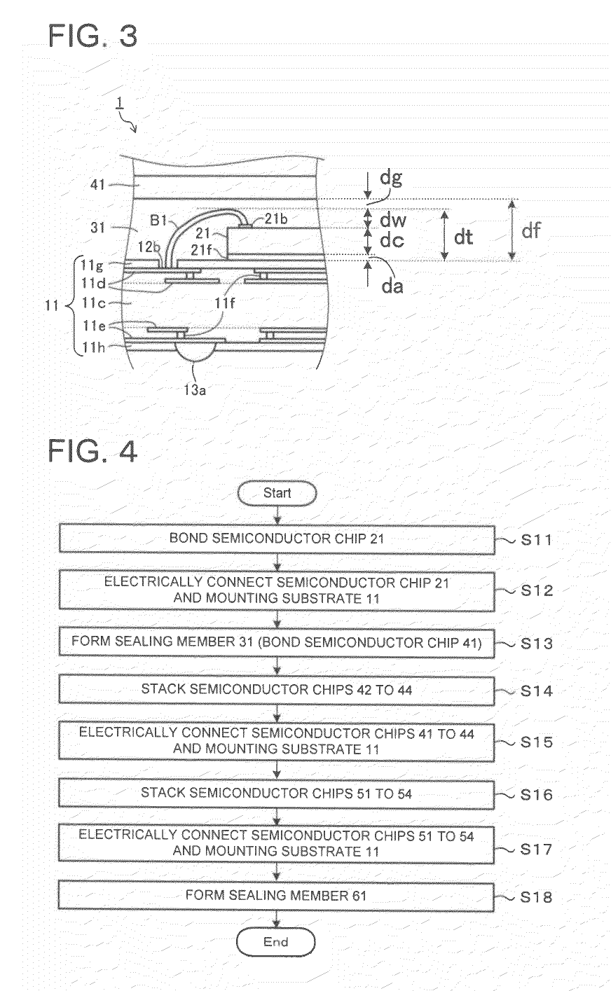

FIG. 1 is a plan view of a semiconductor device 1 according to a first embodiment. FIG. 2A and FIG. 2B are side views of the semiconductor device 1. FIG. 2A is a side view of the semiconductor device 1 seen in the direction of arrow α in FIG. 1. FIG. 2B is a side view of the semiconductor device 1 seen in the direction of arrow p in FIG. 1. FIG. 3 is an enlarged cross-sectional view of the semiconductor device 1.

Note that in FIG. 1 the illustration of a sealing member 61 and bonding wires B2, B3 is omitted. In FIG. 2A, the semiconductor device 1 is illustrated with the sealing member 61 being in a see-through state. In FIG. 2B, the sealing member 61 is in a see-through state, and the illustration of bonding wires B3 is omitted.

### (Overview of the Semiconductor Device 1)

First, an overview of the semiconductor device 1 will be described. The semiconductor device 1 has a rectangular mounting substrate 11, a rectangular semiconductor chip 21, a sealing member 31, rectangular semiconductor chips 41 to 44, rectangular semiconductor chips 51 to 54, and a sealing member 61. The semiconductor chips 41 to 44 and 51 to 54 are memory chips for writing and reading data, and writing and reading of data to these semiconductor chips 41 to 44 and 51 to 55 are performed by the semiconductor chip 21 which is a control chip (controller).

In this semiconductor device 1, the plural semiconductor chips 41 to 44 and 51 to 54 are divided into two systems (first and second system) for performing writing and reading data. Further, data exchange between the semiconductor chip 21 and the outside is also divided into two systems (third and fourth system). When there is a large difference in wiring length in the systems and between the systems, speeding up of operation of the semiconductor chip is hindered.

As already described, input/output of a signal between the semiconductor chips 41 to 44, 51 to 55 and the outside are performed via the semiconductor chip 21. In this embodiment, the semiconductor chip 21 is disposed in the vicinity of the center of the mounting substrate 11, thereby facilitating making the wirings between external connection terminals 13a, 13b and the semiconductor chip 21 have equal length (or have approximately equal length, which will be simply described as “have equal length” below). Further, the semiconductor chips 41 to 44, 51 to 55 are disposed on the semiconductor chip 21, thereby facilitating making the wirings between the semiconductor chip 21 and the semiconductor chips 41 to 44, 51 to 55 have equal length.

To make the wirings have equal length, it is conceivable to stack the semiconductor chip 21 and the semiconductor chips 41 to 44, 51 to 55 in separate packages (Package On Package). That is, the connection between the chips and the substrate can be set in each semiconductor package, and this facilitates a high-speed operation. However, producing plural packages often leads to high costs, and tends to make the entire thickness large. In this respect, in this embodiment, a thin semiconductor device 1 with equal-length wirings can be produced at relatively low cost.

In particular, the semiconductor device 1 is structured such that, by contriving disposition and so on of the semiconductor chip 21, the semiconductor chips 41 to 44 and the semiconductor chips 51 to 54 on the mounting substrate 11, the wiring length is substantially equal in the systems and between the systems. Specifically, it is structured such that a specific wiring (first system) among the wirings connecting the semiconductor chip 21 and the semiconductor chips 41 to 44 and a specific wiring (second system) among the wirings connecting the semiconductor chip 21 and the semiconductor chips 51 to 54 have substantially the same wiring length, and moreover, a specific wiring (third system) among the wirings connecting the semiconductor chip 21 and the external connection terminals 13a of the mounting substrate 11 and a specific wiring (fourth system) among the wirings connecting the semiconductor chip 21 and the external connection terminals 13b of the mounting substrate 11 have substantially the same wiring length. Here, note that the specific wirings refer to a wiring used for communicating a data signal (IO) or a timing signal specifying timing of read/write of data.

### (Structure of the Semiconductor Device 1)

Hereinafter, the structure of the semiconductor device 1 will be described.

The mounting substrate 11 has a first main surface 11a and a second main surface 11b corresponding to a front surface and a rear surface. The mounting substrate 11 is a rectangular substrate having a first to fourth side (side surface) A to D. As illustrated in FIG. 3, the mounting substrate 11 has a core layer 11c, wiring layers 11d, 11e, an interlayer connecting part 11f, and solder resist layers 11g, 11h. The core layer 11c is a resin layer (using a glass-epoxy resin or a glass-bismaleimide triazine resin for example) having a thickness of, for example, 50 μm to 300 μm. For example, Cu is used for the wiring layers 11d, 11e, one or more of which are disposed on both surfaces of the core layer 11c. To the wiring layers 11d, 11e, connection terminals 12a to 12f and external connection terminals 13a, 13b are connected. The solder resist layers 11g, 11h are resin layers (using an epoxy resin for example) disposed outside the wiring layers 11d, 11e, respectively. At positions where the connection terminals 12a to 12f and the external connection terminals 13a, 13b are disposed, openings are formed in the solder resist layers 11g, 11h.

On the first main surface 11a of the mounting substrate 11, the connection terminals 12a to 12d for the semiconductor chip 21 are formed on sides of the first to fourth side A to D, respectively. Further, on the first main surface 11a of the mounting substrate 11, the connection terminals 12e for the semiconductor chips 41 to 44 and the connection terminals 12f for the semiconductor chips 51 to 54 are formed along the first and second sides A, B respectively.

The connection terminals 12a to 12f are made by, for example, electrolytic plating of nickel (Ni) and gold (Au) on terminals of copper (Cu). Along the third and fourth sides C, D on the second main surface 11b of the mounting substrate 11, the external connection terminals 13a, 13b which are connection terminals for an external substrate or the like are formed respectively. The external connection terminals 13a, 13b are, for example, solder balls or solder bumps.

The semiconductor chip 21 is a rectangular control chip (controller) having a first to fourth side a to d and controlling writing and reading of data to/from the semiconductor chips 41 to 44 and the semiconductor chips 51 to 54. The semiconductor chip 21 is mounted in the vicinity of the center of the mounting substrate 11 with a resin layer 21f (using a thermosetting resin for example).

The semiconductor chip 21 has plural electrodes 21a to 21d formed along the sides a to d, which correspond to the sides A to D, respectively, of the mounting substrate 11. The electrodes 21a to 21d are, for example, aluminum pads. The semiconductor chip 21 is mounted on the first main surface 11a of the mounting substrate 11. The electrodes 21a to 21d of the semiconductor chip 21 are connected electrically by bonding wires B1 to the connection terminals 12a to 12d, respectively, of the mounting substrate 11. The material of the bonding wires B1 is gold (Au) or copper (Cu) for example.

The sealing member 31 buries the semiconductor chip 21 together with the bonding wires B1. For the sealing member 31, a thermosetting resin is used for example. The sealing member 31 is formed on the front surface of and around the semiconductor chip 21 so that its front surface (upper surface) is at a position higher than upper ends of the bonding wires B1. Further, the sealing member 31 is formed so that its size (vertical and horizontal length) is substantially the same as the size (vertical and horizontal length) of a rear surface of the semiconductor chip 41 stacked on the front surface (upper surface).

FIG. 3 represents details of the structure of the semiconductor device 1 in the vicinity of the sealing member 31. On the mounting substrate 11 (solder resist layer 11g), the semiconductor chip 21 is mounted via the resin layer 21f. The semiconductor chip 21 and the bonding wires B1 are sealed by the sealing member 31. The semiconductor chip 41 is disposed on this sealing member 31.

At this time, the thickness df, distance dg, height dw, and thicknesses dc, da, dt illustrated in FIG. 3 are defined as follows.

Specifically, the thickness df is the thickness of the sealing member 31, and is defined by the distance between the mounting substrate 11 and the semiconductor chip 41.

The distance dg is the distance (clearance) between the semiconductor chip 41 and the maximum height of the bonding wires B1.

The height dw is the distance between the semiconductor chip 21 and the maximum height of the bonding wires B1.

The thickness dc is the thickness of the semiconductor chip 21.

The thickness da is the thickness of the resin layer 21f.

The thickness dt is the distance between the mounting substrate 11 and the maximum height of the bonding wires B1, and is also the sum of the height dw, the thickness dc, and the thickness da.

Setting the thickness df and so on as follows facilitates producing a semiconductor device 1 which achieves both prevention of contact between the bonding wires B1 and the semiconductor chip 41 and thinning of the semiconductor device 1. Specifically, such a semiconductor device 1 can be produced following a production procedure (FIG. 4) which will be described later. Note that these values are taken as target values in example 1, which will be described later.

Thickness df: 125 μm to 145 μm (135 μm±10 μm)

Distance dg: at least 5.7 μm

Height dw: 30 μm to 90 μm (60 μm±30 μm)

Thickness dc: 25 μm to 35 μm (30 μm±5 μm)

Thickness da: 3 μm to 11 μm (7 μm±4 μm)

Thickness dt: 65 μm to 129 μm (97 μm±32 μm)

The semiconductor chips 41 to 44 are memory chips for writing and reading data. The semiconductor chips 41 to 44 have electrodes 41a to 44a, respectively, on one side of their front surface. The electrodes 41a to 44a are, for example, aluminum pads. The semiconductor chips 41 to 44 are stacked on the sealing member 31 in a manner that their positions are shifted so that the sides on which the electrodes 41a to 44a are formed are along the side A of the mounting substrate 11. For example, by stacking the semiconductor chips 41 to 44 in a manner that their positions are shifted in the range of 0.1 mm to 1.0 mm, a space for bonding to the electrodes 41a to 44a is secured.

The electrodes 41a to 44a of the semiconductor chips 41 to 44 are connected electrically to the connection terminals 12e of the mounting substrate 11 by bonding wires B2. At least parts of the electrodes 41a to 44a of the semiconductor chips 41 to 44 are electrically connected to each other by the bonding wires B2. The material of the bonding wires B2 is, for example, gold (Au) or copper (Cu).

The semiconductor chips 51 to 54 are memory chips for writing and reading data. The semiconductor chips 51 to 54 have electrodes 51a to 54a, respectively, on one side of their front surface. The electrodes 51a to 54a are, for example, aluminum pads. The semiconductor chips 51 to 54 are stacked on the semiconductor chips 41 to 44 in a manner that their positions are shifted so that the sides on which the electrodes 51a to 54a are formed are along the side B of the mounting substrate 11. For example, by stacking the semiconductor chips 51 to 54 in a manner that their positions are shifted in the range of 0.1 mm to 1.0 mm, a space for bonding to the electrodes 51a to 54a is secured.

The electrodes 51a to 54a of the semiconductor chips 51 to 54 are connected electrically to the connection terminals 12f of the mounting substrate 11 by bonding wires B3. At least parts of the electrodes 51a to 54a of the semiconductor chips 51 to 54 are electrically connected to each other by the bonding wires B3. The material of the bonding wires B3 is, for example, gold (Au) or copper (Cu).

The sealing member 61 is a sealing resin (for example, a molding resin having an epoxy resin, silica filler, and/or carbon powder (carbon black) as main components) which seals the semiconductor chip 21, the sealing member 31, the semiconductor chips 41 to 44, and the semiconductor chips 51 to 54.

In this embodiment, the amount of impurity ions (Cl ions and Br ions) contained in the resins in the mounting substrate 11 (core layer 11c and solder resist layers 11g, 11h) and the sealing member 31 is limited. Specifically, a ratio K of the total amount (weight) of Cl ions and Br ions contained in the resins (core layer and solder resist layers 11g, 11h) in the mounting substrate 11 and the sealing member 31 is about 15 ppm (more precisely, 13.5 ppm) or lower. This ratio K is represented by the ratio of the total weight W1 (g) of Cl ions and Br ions in the core layer 11c, the solder resist layers 11g, 11h, and the sealing member 31 to the total weight W0 (g) of the core layer 11c, the solder resist layers 11g, 11h, and the sealing member 31 (K=W1/W0).

It is possible that an alloy layer (AuAl or CuAl alloy) of a joining part of the electrodes 21a to 21d (for example, Al) of the semiconductor chip 21 and the bonding wires B1 (for example, Au or Cu) is corroded by Cl ions and Br ions. As will be described later, when the semiconductor device 1 is operated at high temperatures and at high humidity, it is possible that this alloy layer is corroded. By setting the ratio K of Cl ions and Br ions contained in the resins (core layer 11c and solder resist layers 11g, 11h) in the mounting substrate 11 and the sealing member 31 to about 15 ppm or lower, it becomes possible to suppress this corrosion.

Water permeability of the sealing member 31 affects this corrosion. As will be described later, the sealing member 31 is formed of a resin material having a certain degree of fluidity. Thus, it is difficult to put a large amount of filler in this resin material. Consequently, the sealing member 31 tends to have high water permeability as compared to the sealing member 61 for example, and possibly has, for example, water permeability that is 2 to times larger. In other words, conversely, the sealing member 61 has relatively low water permeability, and since it is separated to some extent from the electrodes 21a to 21d of the semiconductor chip 21, the sealing member has a small effect on the corrosion in the vicinity of the electrodes 21a to 21d.

Note that it is unnecessary for halogen ions in the resin layer 21f to be 15 ppm or less. This is because, since the surface of the resin layer 21f on the semiconductor chip 21 side is covered with the semiconductor chip 21 which has quite low water permeability, the amount of Cl ions and Br ions reaching the electrodes 21a to 21d of the semiconductor chip 21 is small.

As described above, considering the water permeability and the distance to the electrodes 21a to 21d, what becomes a problem is the amount of halogen ions (Cl ions and Br ions) in the core layer 11c, the solder resist layers 11g, 11h, and the sealing member 31. Thus, the ratio K of halogen ions can be expressed with reference to the weight W0 of the core layer 11c, the solder resist layers 11g, 11h, and the sealing member 31.

### (Creation of the Semiconductor Device 1)

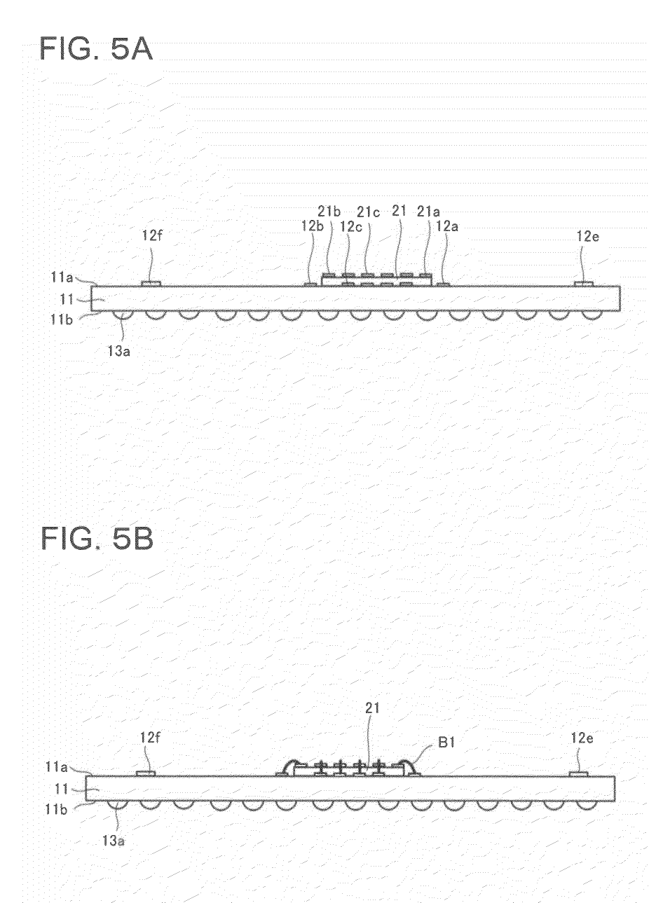

FIG. 4 is a flowchart illustrating a production procedure of the semiconductor device 1. FIG. 5A to FIG. 8B are views illustrating the production procedure of the semiconductor device 1. Hereinafter, the production procedure of the semiconductor device 1 will be described with reference to FIG. 4 to FIG. 8B. Note that the same components as those described in FIG. 1 to FIG. 3 are given the same reference numerals, and duplicating descriptions are omitted.

1. Bonding the Semiconductor Chip 21 (Step S11, FIG. 5a)

The mounting substrate 11 is prepared, and the semiconductor chip 21 is mounted on the first main surface 11a of this mounting substrate 11. At this time, the semiconductor chip 21 is mounted on the first main surface 11a of the mounting substrate 11 so that the sides a to d of the semiconductor chip 21 correspond to the sides A to D of the mounting substrate 11. Note that when the semiconductor chip 21 is cut out of the semiconductor substrate (wafer), a bonding film (resin layer 21f) is attached on a rear surface of the semiconductor chip 21, and the semiconductor chip 21 is mounted using this film.

### 2. Electrically Connecting the Semiconductor Chip 21 and the Mounting Substrate 11 (Step S12, FIG. 5B)

The connection terminals 12a to 12d of the mounting substrate 11 and the electrodes 21a to 21d of the semiconductor chip 21 are electrically connected respectively by the bonding wires B1. At this time, joining parts (alloy layers) of the electrodes 21a to 21d and the bonding wires B1 are formed. As already described, it is possible that these alloy layers are corroded.

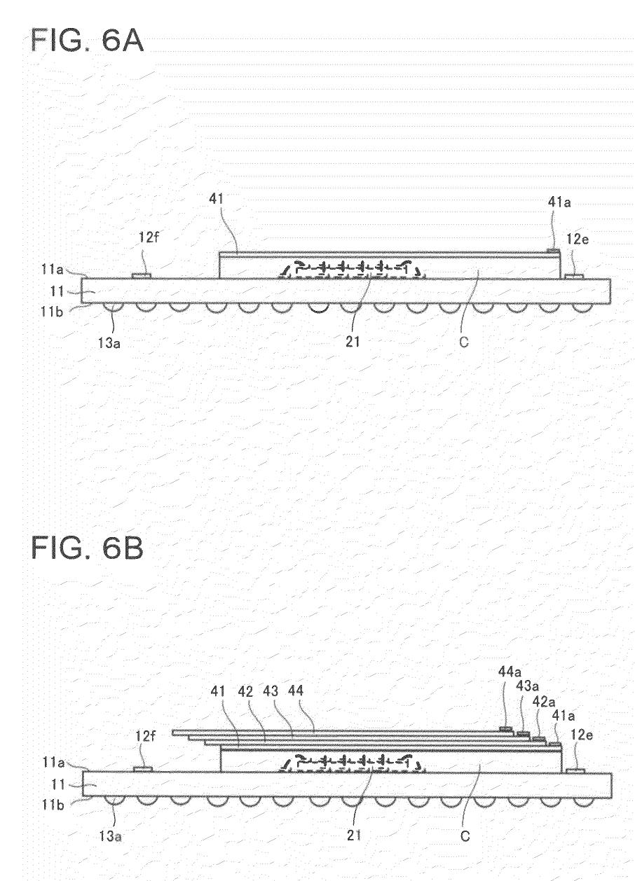

### 3. Forming the Sealing Member 31 (Bonding the Semiconductor Chip 41) (Step S13, FIG. 6A)

On the front surface of and around the semiconductor chip 21, the sealing member 31 is formed. For this purpose, the semiconductor chip 41 with a thermosetting resin layer being formed on its rear surface is prepared. By stacking this semiconductor chip 41 on the semiconductor chip 21 and curing the thermosetting resin layer, the sealing member 31 is formed. That is, forming the sealing member 31 and bonding the semiconductor chip 41 are performed in parallel. Details of this can be presented in the following steps (1) to (4).

### (1) Forming the Thermosetting Resin Layer on the Semiconductor Chip 41

On the rear surface of the semiconductor chip 41, the thermosetting resin layer is formed. On the rear surface of the semiconductor chip 41, for example, a thermosetting resin having a thickness of 50 μm to 200 μm is applied. On the rear surface of the semiconductor chip 41, a film-formed thermosetting resin may also be attached.

### (2) Adjusting the Viscosity of the Thermosetting Resin Layer

The viscosity of the thermosetting resin layer is adjusted. For example, the thermosetting resin layer is heated with a heater (raised to a temperature at which thermosetting proceeds), and is softened to have a viscosity of 300 Pa·s to 10000 Pa·s. By adjusting the viscosity of the thermosetting resin layer, the sealing member 31 with a proper thickness is made, allowing to prevent the upper end of the bonding wires B1 from contacting the rear surface of the semiconductor chip 41. Further, deformation of the bonding wires B1 and occurrence of a void between the sealing member 31 and the semiconductor chip 21 are prevented.

### (3) Mounting the Semiconductor Chip 41 on the Semiconductor Chip

The semiconductor chip 41 having the thermosetting resin layer is mounted on the semiconductor chip 21. As already described, since the viscosity of the thermosetting resin layer is adjusted, the thermosetting resin layer when mounted has a proper thickness. Further, deformation of the bonding wires B1 and occurrence of a void between the sealing member 31 and the semiconductor chip 21 are prevented.

Note that since the thermosetting resin layer would be cured finally, the semiconductor chip 41 is mounted on the semiconductor chip 21 before the curing does not proceed substantially.

### (4) Curing the Thermosetting Resin Layer

By curing the thermosetting resin layer, the sealing member 31 is formed. Since the thermosetting resin layer is raised in temperature, thermosetting proceeds. As already described, the thermosetting resin layer is temporarily softened by being heated (adjustment of viscosity), but it is cured finally due to the proceeding of thermosetting.

The formed sealing member 31 has a front surface (upper surface) at a higher position than the upper end of the bonding wires B1, and a size (vertical and horizontal length) substantially equal to the size (vertical and horizontal length) of the rear surface of the semiconductor chip 41 stacked on the front surface (upper face). The sealing member 31 can have, for example, the already described thickness df of 125 μm to 145 μm.

4. Stacking the Semiconductor Chips 42 to 44 (Step S14, FIG. 6b)

The semiconductor chips 42 to 44 are stacked on the semiconductor chip 41. At this time, their positions are shifted on the sealing member 31 so that the sides on which the electrodes 41a to 44a are formed are along the side A of the mounting substrate 11. Note that when the semiconductor chips 42 to 44 are cut out of the semiconductor substrate (wafer), a bonding film is attached on a rear surface of each of the semiconductor chips 42 to 44. 2.

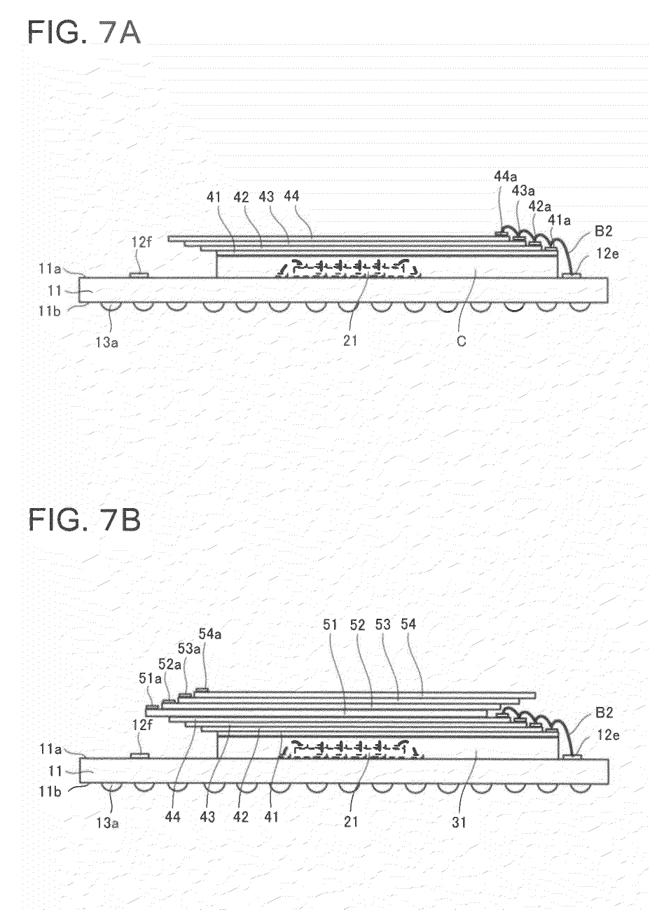

5. Electrically Connecting the Semiconductor Chips 41 to 44 and The Mounting Substrate 11 (Step S15, FIG. 7a)

The electrodes 41a to 44a of the semiconductor chips 41 to 44 and the connection terminals 12e of the mounting substrate 11 are connected with bonding wires B2. Note that in the bonding, sequential connection may be performed from the connection terminals 12e side of the mounting substrate 11 to the electrodes 44a side of the semiconductor chip 44, or sequential connection may be performed from the electrodes 44a side of the semiconductor chip 44 to the connection terminals 12e side of the mounting substrate 11.

6. Stacking the Semiconductor Chips 51 to 54 (Step S16, FIG. 7b)

The semiconductor chips 51 to 54 are stacked on the surface of the stacked semiconductor chip 44 in a manner that their positions are shifted so that the sides on which the electrodes 51a to 54a are formed are along the side B of the mounting substrate 11. Note that when the semiconductor chips 51 to 54 are cut out of the semiconductor substrate (wafer), a bonding film is attached on a rear surface of each of the semiconductor chips 51 to 54.

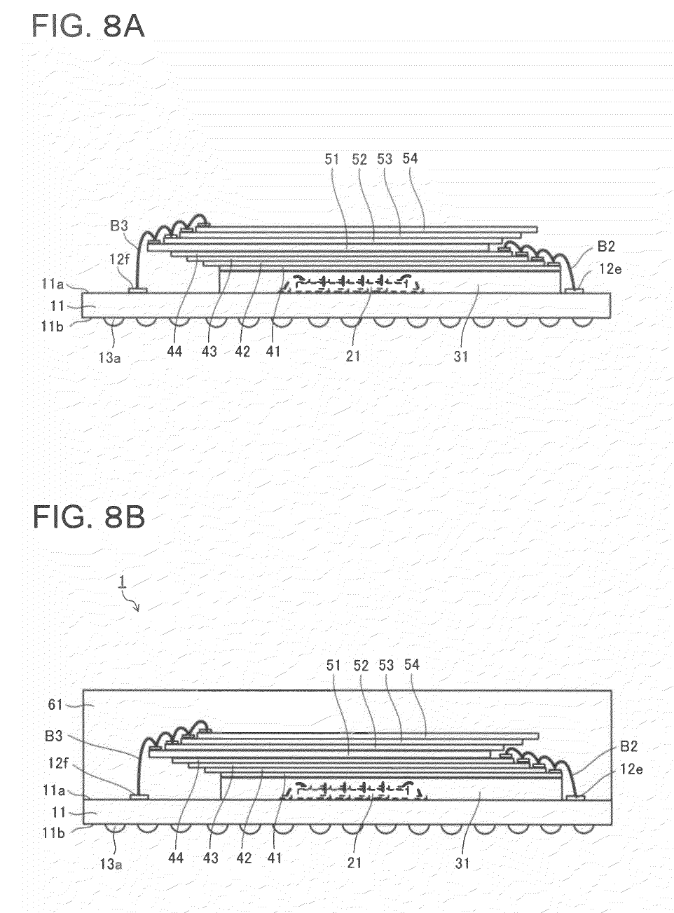

7. Electrically Connecting the Semiconductor Chips 51 to 54 and The Mounting Substrate 11 (Step S17, FIG. 8a)

The electrodes 51a to 54a of the semiconductor chips 51 to 54 and the connection terminals 12f of the mounting substrate 11 are connected by bonding wires B3. Note that in the bonding, sequential connection may be performed from the connection terminals 12f side of the mounting substrate 11 to the electrodes 54a side of the semiconductor chip 54, or sequential connection may be performed from the electrodes 54a side of the semiconductor chip 54 to the connection terminals 12f side of the mounting substrate 11.

8. Forming the Sealing Member 61 (Step S18, FIG. 8b)

The semiconductor chip 21, the semiconductor chips 41 to 44 and the semiconductor chips 51 to 54 mounted on the first main surface 11a of the mounting substrate 11 are sealed with a sealing resin (molding resin) which is to be the sealing member 61. As the molding resin, one having an epoxy resin, silica filler and/or carbon powder (carbon black) as main components may be used.

Thereafter, the external connection terminals 13a, 13b (solder balls or the like) are joined to the mounting substrate 11.

### Second Embodiment

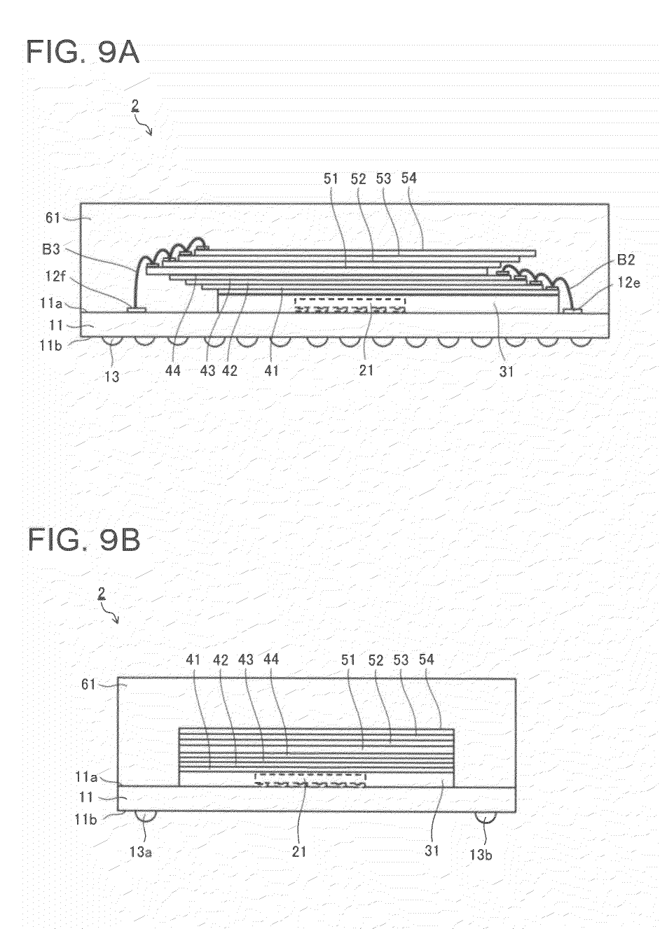

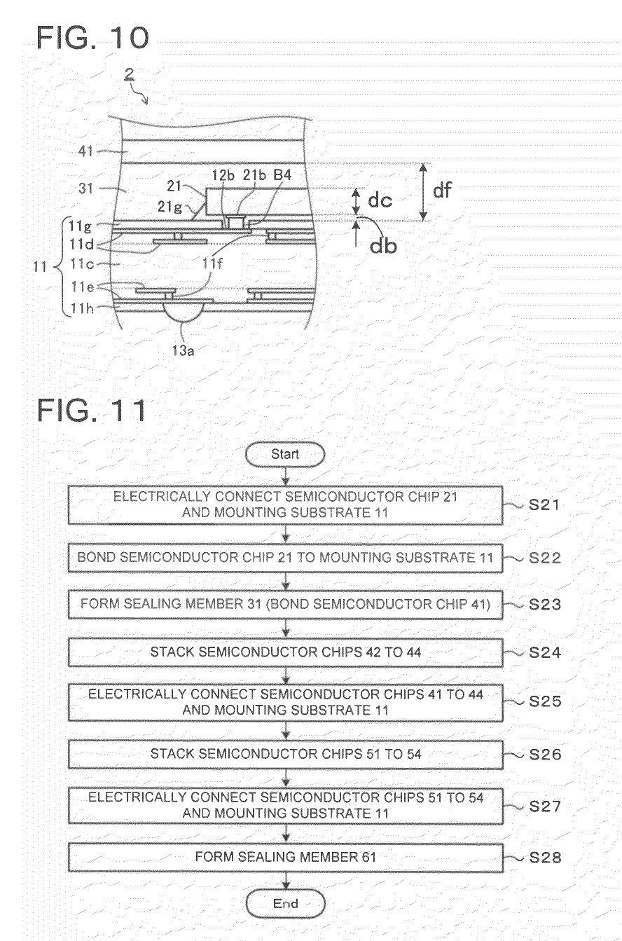

FIG. 9A and FIG. 9B are side views of a semiconductor device 2 according to a second embodiment. FIG. 9A is a side view of the semiconductor device 2 seen in the direction of arrow α in FIG. 1. FIG. 9B is a side view of the semiconductor device 2 seen in the direction of arrow in FIG. 1. FIG. 10 is an enlarged cross-sectional view of the semiconductor device 2.

Note that in FIG. 9A, the semiconductor device 2 is illustrated with a sealing member 61 being in a see-through state. In FIG. 9B, the sealing member 61 is in a see-through state, and the illustration of bonding wires B3 is omitted.

Hereinafter, the structure of the semiconductor device 2 will be described with reference to FIG. 9A, FIG. 9B, FIG. 10, where the same components as those of the semiconductor device 1 described in FIG. 1 to FIG. 3 are given the same reference numerals, and duplicating descriptions are omitted.

In this semiconductor device 2, the upper surface of a semiconductor chip 21 is positioned on a lower side, and electrodes 21a to 21d of the semiconductor chip 21 are connected electrically to connection terminals 12a to 12d of amounting substrate 11 (what is called a flip-chip connection) by joining terminals B4. The joining terminals B4 are formed of metal including Au or Cu, for example. The semiconductor chip 21 is mounted to the mounting substrate 11 with a resin layer (for example, a layer of thermosetting resin) 21g.

Similarly to the first embodiment, the thickness df of the sealing member 31 can be set to 125 μm to 145 μm (135±10 μm). The thickness dc of the semiconductor chip 21 can be set to 25 μm to 35 μm (30 μm±5 μm). The distance db between the mounting substrate 11 and the semiconductor chip 21 can be set to 4 μm to 10 μm (6 μm±3 μm).

Setting the thickness df and so on in this manner facilitates producing the semiconductor device 2. Specifically, such a semiconductor device 2 can be produced following a production procedure (FIG. 11) which will be described later.

Also in this embodiment, the amount of impurity ions (Cl ions and Br ions) contained in the resins (core layer 11c and solder resist layers 11g, 11h) in the mounting substrate 11 and the sealing member 61 is limited. An alloy layer (AuAl or CuAl alloy) may be formed between the electrodes 21a to 21d and the joining terminals B4. In this case, similarly to the first embodiment, it is possible that this alloy layer is corroded by Cl ions and Br ions.

Specifically, a ratio K1 of the total weight of Cl ions and Br ions contained in the resins (core layer 11c and solder resist layers 11g, 11h) in the mounting substrate 11, the sealing member 31, and the resin layer 21g is 15 ppm or lower. This ratio K is represented by the ratio of the total weight W11 of Cl ions and Br ions in the core layer 11c, the solder resist layers 11g, 11h, the sealing member 31, and the resin layer 21g to the total weight W10 of the core layer 11c, the solder resist layers 11g, 11h, the sealing member 31, and the resin layer 21g (K=W11/W10). The reason for calculating the ratio K1 by including the resin layer 21g is that the water permeability of the resin layer 21g is large to a certain degree, and it is in proximity to the electrodes 21a of the semiconductor chip 21. Setting the ratio K1 to about ppm or lower makes it possible to suppress this corrosion.

### (Production of the Semiconductor Device 2)

The semiconductor device 2 can be produced following the procedure illustrated in FIG. 11.

Attachment of the semiconductor chip 21 to the mounting substrate 11 is performed as follows.

### 1. Electrically Connecting the Semiconductor Chip 21 and the Mounting Substrate 11 (Step S21)

The semiconductor chip 21 and the mounting substrate 11 are connected electrically. The connection terminals 12a to 12e of the mounting substrate 11 are made by, for example, electrolytic plating of Au/Pd/Ni or the like and solder plating.

Solder plating and Au bumps are formed on the electrodes 21a to 21d of the semiconductor chip 21.

After the semiconductor chip 21 is mounted on the mounting substrate 11, the solder plating and soon are heated to, for example, 200° C. to 260° C. by a reflow apparatus to melt it. As a result, the mounting substrate 11 and the semiconductor chip 21 are joined by the solder plating and so on (formation of the joining terminals B4).

### 2. Bonding the Semiconductor Chip 21 to the Mounting Substrate 11 (Step S22)

After the electrical connection in step S21, the mounting substrate 11 and the semiconductor chip 21 are bonded with a thermosetting adhesive or the like (formation of the resin layer 21g). Note that the semiconductor chip 21 may be bonded to the mounting substrate 11 before joining of the mounting substrate 11 and the semiconductor chip 21.

### 3. Forming the Sealing Member 31 (Mounting the Semiconductor Chip 41) (Step S23)

The sealing member 31 can be formed similarly to the first embodiment. That is, a thermosetting resin layer is formed on the rear surface of the semiconductor chip 41, and is heated to make it have a viscosity of 300 Pa·s to 10000 Pa·s. Thereafter, this semiconductor chip 41 can be mounted on the semiconductor chip 21, and the thermosetting resin layer can be cured. As a result, similarly to the first embodiment, the sealing member 31 having the thickness df (125 μm to 145 μm (135 μm±10 μm)) can be made.

Thereafter, following a procedure similar to that for the first embodiment, the semiconductor device 2 is produced. Details of this are not substantially different from those in the first embodiment, and hence are omitted.

### Example 1

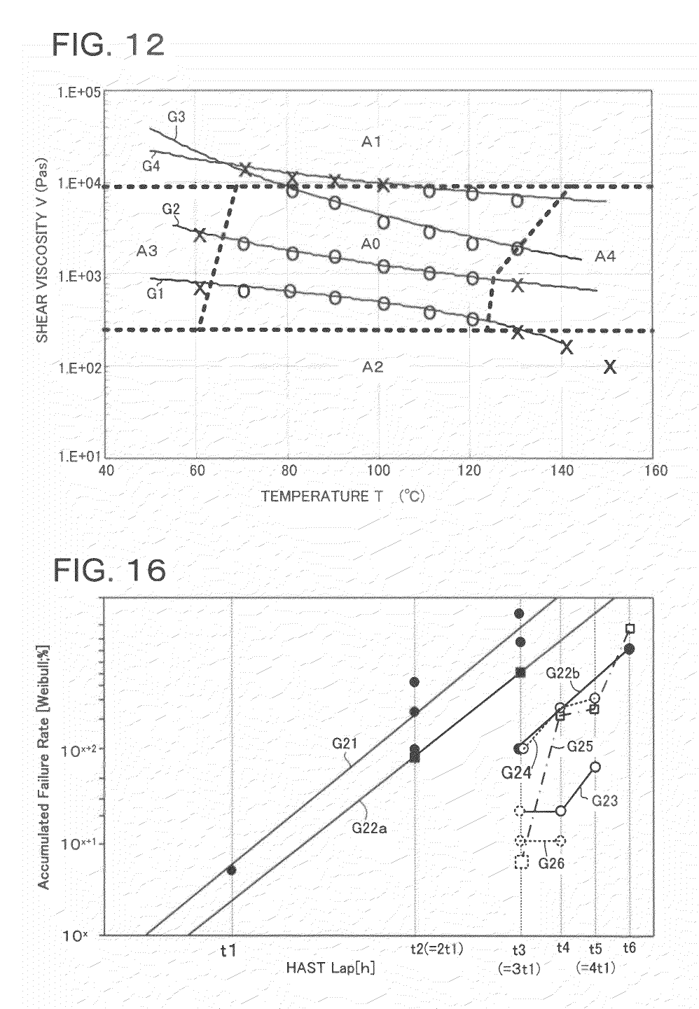

FIG. 12 is a graph representing a relation between a shear viscosity and a temperature T of the thermosetting resin used for forming the sealing member 31. Graphs G1 to G4 correspond to thermosetting resins M1 to M4 having different compositions.

Here, the sealing member 31 is formed with each of the thermosetting resins M1 to M4 by changing their temperatures. Whether the semiconductor device 1 is good or bad at this point is represented as “O”, “X” on the graphs. “O”, “X” correspond to good product, bad product, respectively. Note that this good or bad is determined with reference to whether the thickness df and so on are in the already-described ranges (125 μm to 145 μm, and so on).

As illustrated in FIG. 12, an area A0 in which a good product can be obtained is represented by a parallelogram with a vertical side and a horizontal side being the shear viscosity V and the temperature T, respectively. On the other hand, in an area A1, deformation of the bonding wires B1 and expansion of the sealing member 31 (thickness df below the standard) occurred due to the shear viscosity V being large. In an area A2, voids in the sealing member 31 and extrusion of the sealing member 31 occurred due to the shear viscosity V being small. In an area A3, due to low temperatures, the bonding strength between the sealing member 31 and the mounting substrate 11 was insufficient. In an area A4, due to high temperatures, voids (bubbles) occurred between the bonding wires B1 and the semiconductor chip 21.

The shear viscosity V of the area A0 in which a good product can be obtained is about 250 pa·s to about 10 kpa·s. Further, the temperature T is 60° C. to 140° C. This temperature T is a thermosetting starting temperature or the like of the thermosetting resins M1 to M4, namely, a parameter which varies depending on the material used. On the other hand, the shear viscosity V conceivably has a certain degree of universality. That is, even when the thermosetting resin to be used is changed, the range of the proper shear viscosity V does not change largely. Note that the shear viscosity V can be measured using a viscosity measuring apparatus. The shear viscosity V is measured under vibrations of 1 Hz.

As above, it was found that the sealing member 31 having the proper thickness df and so on can be made by using the liquid thermosetting resin with the shear viscosity V of about 250 pa·s to about 10 kpa·s.

### Example 2

As already described, it is possible that an alloy layer (AuAl or CuAl alloy) of a joining part of the electrodes 21a to 21d (for example, Al) of the semiconductor chip 21 and the bonding wires B1 (for example, Au or Cu) is corroded by Cl ions and Br ions.

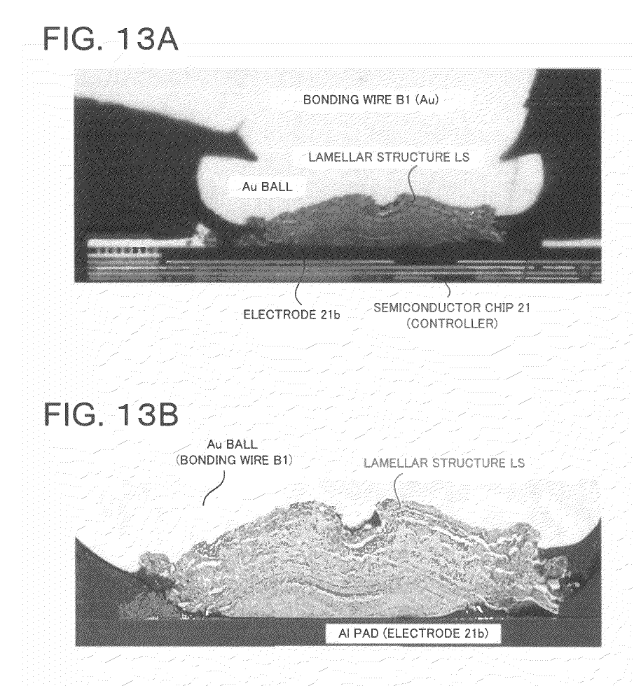

FIG. 13A and FIG. 13B represent a lamellar structure LS which occurred in the alloy layer of this joining part when the semiconductor device 1 is operated at high temperatures and high humidity. FIG. 13A and FIG. 13B are different in scale. FIG. 13B represents a state that FIG. 13A is further enlarged. It can be seen that a structure (lamellar structure) LS constituting a layer is formed between the electrodes 21a to 21d and the bonding wires B1. Here, the electrodes 21a to 21d are formed of Al, and the bonding wires B1 are formed of Au. As will be described later, this lamellar structure LS includes a layer of high-resistance AlCl₃, which largely affects the reliability of electrical connection between the electrodes 21a to 21d and the bonding wires B1.

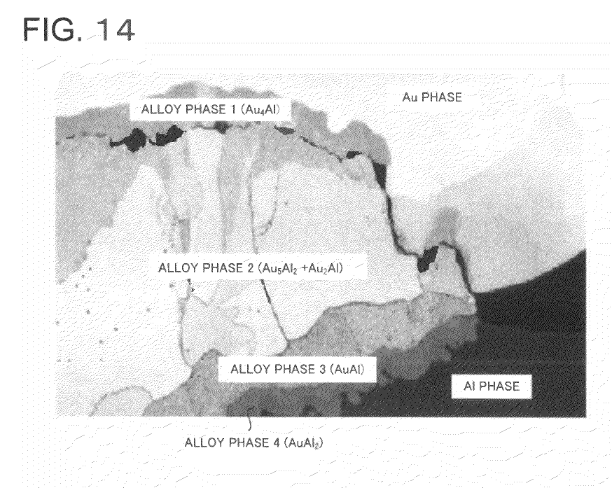

The mechanism of occurrence of the lamellar structure LS will be described. FIG. 14 represents a state of the alloy in the joining part when the electrodes 21a to 21d and the bonding wires B1 are formed of Al and Au, respectively. An alloy phase 1 (Au₄Al), an alloy phase 2 (phase in which an Au₅Al₂ phase and an Au₂Al phase are mixed), an alloy phase 2 (AuAl phase), and an alloy phase 4 (AuAl₂) are disposed between an Au phase (bonding wire B1) and an Al phase (electrode 21b). Among them, the alloy phase 1 (Au₄Al) is corroded by Cl ions and so on.

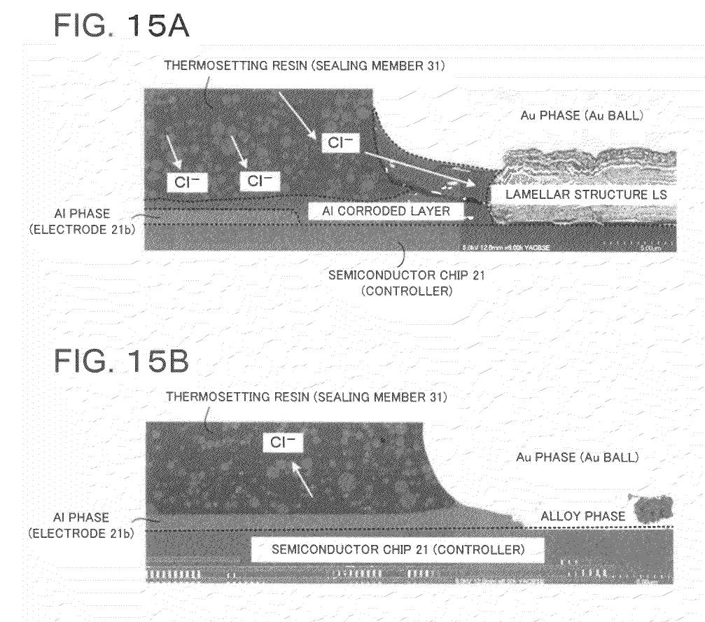

FIG. 15A and FIG. 15B are views representing a state of the joining part of the electrodes 21a to 21d and the bonding wires B1 when the semiconductor device 1 is operated at high temperatures and high humidity. As already described, the sealing member 31 has relatively high water permeability. This point is not largely different in the resins (core layer 11c and solder resist layers 11g, 11h) in the mounting substrate 11. Thus, at high temperatures and high humidity, it is possible that the resins (core layer 11c and solder resist layers 11g, 11h) in the sealing member 31 and the mounting substrate 11 contain moisture which allows Cl ions and Br ions therein to move easily, and this possibly becomes a factor for corrosion of the alloy phase 1 (Au₄Al).

In FIG. 15A, a positive voltage is applied (Vcc pad) to the electrodes 21a to 21d. Accordingly, Cl ions and so on in the sealing member 31 are pulled to the electrodes 21a to 21d and react with the alloy phase 1 (Au₄Al) as follows.

Au₄Al+3Cl₃→AlCl₃+4Au

Specifically, “Au₄Al” is corroded and becomes “AlCl₃”, and is meanwhile reduced and becomes “Au”. As a result, the lamellar structure LS is formed, which is made by stacking of a high-resistance layer of “AlCl₃” and a low-resistance layer of “Au”. As already described, the high-resistance layer is a cause of impairing the reliability of electrical connection.

Due to the voltage being applied under high temperatures, the layer of reduced “Au” is possibly alloyed with Al as follows and becomes “Au₄Al” again.

4Au+Al→Au₄Al

Thus, corrosion and reduction of “Au₄Al”, alloying of Au which occurred from reduction (reoccurrence of “Au₄Al”), and corrosion and reduction of reoccurred “Au₄Al” are repeated, and the lamellar structure LS grows continuously. As a result, a connection failure occurs in the electrodes 21a to 21d to which the positive voltage is applied.

On the other hand, in FIG. 15B, the electrodes 21a to 21d are in a grounded state (Vss pad). Accordingly, Cl ions and so on in the sealing member 31 moves away from the electrodes 21a to 21d, and will not react with the alloy phase 1 (Au₄Al). Thus, when the semiconductor device 1 is tested in an operating state, whether there is corrosion or not differs depending on whether there is application of voltage to the electrodes 21a to 21d, or the like (for example, whether the electrodes 21a to 21d are Vcc pads or Vss pads).

As described above, by applying electricity to the semiconductor device 1 at high temperatures and high humidity, for example, the joining part (alloy phase 1 (Au₄Al)) of the electrodes 21a to 21d and the bonding wires B1 corrodes. To limit the progress of this corrosion, the amount of impurity ions (Cl ions and Br ions) contained in the resins (core layer 11c and solder resist layers 11g, 11h) in the mounting substrate 11 and the sealing member 61 is limited. Specifically, the ratio K of the total weight K of Cl ions and Br ions contained in the resins (core layer 11c and solder resist layers 11g, 11h) in the mounting substrate 11 and the sealing member 61 is about 15 ppm (more precisely, 13.5 ppm) or lower.

FIG. 16 is a diagram illustrating results of an operating test (HAST (Highly Accelerated temperature and humidity Stress Test)) at high temperatures and high humidity. Here, the operating test is conducted at a temperature of 100° C. and humidity of 85%.

The horizontal axis and the vertical axis of the graph represents a test time (HAST Lap) and a failure rate (Accumulated Failure Rate) F, respectively. The failure rate F at each of test times t1 to t6 was measured. Graphs G21, G22 (G22a, 22b) and G23 to G26 represent test results when the ratio (rate) K of the total weight of Cl ions in the resins (core layer 11c and solder resist layers 11g, 11h) in the mounting substrate 11 and the entire sealing member 31 is 26, 23, 20, 18, 17, 12 [ppm], respectively.

Note that in the graphs G23, G25, G26 (when the ratio K of Cl ions is 20, 17, 12 [ppm]) at time t3 and in the graphs G23, G26 (when the ratio K of the total weight of Cl ions is 20, 12 [ppm]) at time t4, no failure occurred in the tested sample. Accordingly, in these cases, a tentative failure rate F0 was calculated assuming that one failure occurred in the sample. That is, the tentative failure rate F0 larger than an actual failure rate F1 is plotted on the graph.

As illustrated in this diagram, it can be seen that, as the ratio K of Cl ions gets lower, the failure rate F decreases. That is, the graphs G21 to G26 tend to move in a rightward and downward direction. It was found that, when the ratio K1 of the total weight of Cl ions is 13.5 ppm or lower, the reliability of the semiconductor device 1 can be increased sufficiently.

At this time, the ratio K2 of Cl ions in the sealing member 31 is 7.5 ppm or lower, and the ratio K3 of Cl ions in the resins (core layer and solder resist layers 11g, 11h) in the mounting substrate 11 is 6 ppm or lower. This ratio K2 is not referred to the weight of only the sealing member 31, but is referred to the weight W0 of the core layer, the solder resist layers 11g, 11h, and the sealing member 31. Accordingly, when the ratio K2 in the sealing member 31 and the ratio K3 in the mounting substrate 11 are added, the sum equals to the ratio K1 in the sealing member 31 and the mounting substrate 11 (core layer and solder resist layers 11g, 11h).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate;
a first semiconductor chip disposed on the substrate;
an electrode disposed on the first semiconductor chip and containing Al;
a first connection member electrically connecting the electrode and the substrate and containing Au or Cu;
a first sealing member sealing the first semiconductor chip and the first connection member;
one or more second semiconductor chips stacked on the first sealing member;
one or more second connection members electrically connecting the one or more second semiconductor chips and the substrate;
a second sealing member sealing the first connection member, the one or more second semiconductor chips, and the one or more second connection members; and
a ratio of a total weight W1 of Cl ions and Br ions in the first sealing member to a weight W0 of resins of the substrate and the first sealing member being 7.5 ppm or lower.

2. The semiconductor device according to claim 1,
wherein a ratio of a total weight W2 of Cl ions and Br ions in the resin of the substrate to the weight W0 is 6 ppm or lower.

3. The semiconductor device according to claim 1,
wherein the first sealing member is formed by curing a liquid resin material having a viscosity of 250 Pa·s or higher and 10000 Pa·s or lower.

4. The semiconductor device according to claim 1,
wherein the electrode is disposed on a main surface of the first semiconductor chip, the main surface being on the side of the one or more second semiconductor chips; and
wherein the first connection member is a wire.

5. The semiconductor device according to claim 4,
wherein the first sealing member has a thickness of 125 μm or larger and 145 μm or smaller defined by a distance between the substrate and the one or more second semiconductor chips; and
wherein the distance between the substrate and a maximum height of the wire is 64.7 μm or larger and 129.3 μm or smaller.

6. The semiconductor device according to claim 1,
wherein the electrode is disposed on a main surface of the first semiconductor chip, the main surface being on the side of the substrate; and
wherein the first connection member is a bump disposed between the first semiconductor chip and the substrate.
